(19) United States
(12) Patent Application Publication
(10) Pub. No.: US 2025/0380594 A1
(43) Pub. Date: Dec. 11, 2025

(54) DISPLAY MODULE AND DISPLAY APPARATUS

(71) Applicant: BOE TECHNOLOGY GROUP CO., LTD., Beijing (CN)

(72) Inventor: Lu LIU, Beijing (CN)

(73) Assignee: BOE TECHNOLOGY GROUP CO., LTD., Beijing (CN)

(21) Appl. No.: 18/878,636

(22) PCT Filed: Dec. 16, 2022
(86) PCT No.: PCT/CN2022/139656

§ 371 Date: Dec. 23, 2024

(51) Int. Cl. H10K 59/80; H05K 5/02; H05K 5/03; H10K 102/00

(52) U.S. Cl. CPC H10K 59/80; H05K 5/03; H05K 5/0217; H10K 2102/311

(57) ABSTRACT

Disclosed are a display module. The display module display module has a flexible region and rigid regions located at both sides of the flexible region. The display module includes at least one flexible impact-resistant layer, and the impact-resistant layer at least covers the flexible region; when a local region of the impact-resistant layer is subjected to an impact load, an elastic modulus of the local region is positively related to the impact load which the local region is subjected to.

### CROSS REFERENCE TO RELATED APPLICATION

The present application is the U.S. National Stage of International Application No. PCT/CN2022/139656, filed on Dec. 16, 2022, the contents of which are incorporated herein by reference in its entirety for all purposes.

### TECHNICAL FIELD

The present disclosure relates to the display technical field, and in particular, to a display module and a display device.

### BACKGROUND

The developments of flexible display technologies have greatly expanded the application forms of display technologies, and different application forms such as foldable screens, wristband screens, rollable screens, sliding rollable screens have emerged. A flexible display module has a low elastic modulus in a flexible region to achieve deformation. For example, a flexible support component is used in the flexible region for support. However, the flexible display module has poor impact-resistant performance in the flexible region.

It should be noted that the information disclosed in the above background section is only used to enhance understanding of the background of the present disclosure, and therefore may include information that does not constitute prior art known to those of ordinary skill in the art.

### SUMMARY

The purpose of the present disclosure is to overcome the above-mentioned shortcomings of related art and provide a display module and a display device to improve the impact-resistant performance of the display device.

According to an aspect of the present disclosure, there is provided a display module having a flexible region and rigid regions located at both sides of the flexible region, wherein the display module includes at least one flexible impact-resistant layer, and the impact-resistant layer at least covers the flexible region;
wherein when a local region of the impact-resistant layer is subjected to an impact load, an elastic modulus of the local region is positively related to the impact load which the local region is subjected to.

According to an implementation of the present disclosure, a strain rate of the local region of the impact-resistant layer when subjected to the impact load is not greater than 100000 s⁻¹.

According to an implementation of the present disclosure, when a strain rate of the local region of the impact-resistant layer when subjected to the impact load is not smaller than 100 s⁻¹, the elastic modulus of the local region is not lower than 0.1 MPa.

According to an implementation of the present disclosure, when a strain rate of the local region of the impact-resistant layer when subjected to the impact load is between 100 s⁻¹ and 10000 s⁻¹, the elastic modulus of the local region is between 0.01 MPa and 3 GPa.

According to an implementation of the present disclosure, when the local region of the impact-resistant layer is not subjected to the impact load, the elastic modulus of the local region is between 1 KPa and 300 KPa.

According to an implementation of the present disclosure, a thickness of the impact-resistant layer is between 10 microns and 150 microns. According to an implementation of the present disclosure, the impact-resistant layer includes a dispersion matrix and an impact-resistant polymer dispersed in the dispersion matrix.

According to an implementation of the present disclosure, the dispersion matrix is an adhesive, and the impact-resistant layer is directly connected to an adjacent functional stacking layer.

According to an implementation of the present disclosure, the adhesive is a pressure-sensitive adhesive, a heat-sensitive adhesive or a photo-sensitive adhesive.

According to an implementation of the present disclosure, a mass content of the impact-resistant polymer in the impact-resistant layer is between 10% and 90%.

According to an implementation of the present disclosure, a mass content of the impact-resistant polymer in the impact-resistant layer is between 10% and 50%.

According to an implementation of the present disclosure, the impact-resistant layer is mainly formed by an impact-resistant polymer.

According to an implementation of the present disclosure, the impact-resistant polymer includes at least one of the following polymers or a modified polymer of at least one of the following polymers:
polypropylene foam, polystyrene foam, ethylene-vinyl acetate copolymer, borosilicate oligomer.

According to an implementation of the present disclosure, the modified polymer refers to a modified polymer formed by polymerizing a precursor component of the polypropylene foam and/or a precursor component of the polystyrene foam with the polymer.

According to an implementation of the present disclosure, the display module further includes a display panel and a flexible cover which are stacked, and the impact-resistant layer is provided between the display panel and the flexible cover.

According to an implementation of the present disclosure, the display module further includes a reflection reduction layer located between the display panel and the flexible cover;
wherein the impact-resistant layer is provided between the display panel and the reflection reduction layer, and/or the impact-resistant layer is provided between the reflection reduction layer and the flexible cover.

According to an implementation of the present disclosure, the display module further includes a display panel and a support component, and the impact-resistant layer is provided between the display panel and the support component.

According to an implementation of the present disclosure, the display module further includes a back film located between the display panel and the support component;

wherein the impact-resistant layer is provided between the display panel and the back film, and/or the impact-resistant layer is provided between the back film and the support component.

According to an implementation of the present disclosure, the impact-resistant layer covers the rigid regions and the flexible region.

According to an implementation of the present disclosure, the display module further includes a filling layer, the filing layer has a thickness which is the same as a thickness of the impact-resistant layer and is arranged in a same layer as the impact-resistant layer, and the filling layer is provided in the rigid regions.

According to a second aspect of the present disclosure, there is provided a display device, including a roller and the display module described above, wherein the flexible region of the display module is slidable around the roller.

It should be understood that the foregoing general description and the following detailed description are illustrative and explanatory only, and are not intended to limit the present disclosure.

### BRIEF DESCRIPTION OF THE DRAWINGS

The accompanying drawings, which are incorporated in and constitute a part of the specification, illustrate embodiments consistent with the disclosure and together with the specification, serve to explain the principles of the present disclosure. Obviously, the drawings in the following description are only some embodiments of the present disclosure. For those of ordinary skill in the art, other drawings can be obtained based on these drawings without exerting creative efforts.

FIG. 1 is a schematic diagram of a sliding and rolling process of a display module in a display device according to an implementation of the present disclosure.

FIG. 2 is a schematic structural diagram of a display module provided with an impact-resistant layer according to an implementation of the present disclosure.

FIG. 3 is a schematic structural diagram of a display module provided with two impact-resistant layers according to an implementation of the present disclosure.

FIG. 4 is a schematic structural diagram of functional stacking layers of a display module (the impact-resistant layer is not shown) according to an implementation of the present disclosure.

FIG. 5 is a schematic structural diagram of a display module in which an impact-resistant layer is provided between a flexible cover and a reflection reduction layer according to an implementation of the present disclosure.

FIG. 6 is a schematic structural diagram of a display module in which an impact-resistant layer is provided between a display panel and a reflection reduction layer according to an implementation of the present disclosure.

FIG. 7 is a schematic structural diagram of a display module in which an impact-resistant layer is provided between a back film and a display panel according to an implementation of the present disclosure.

FIG. 8 is a schematic structural diagram of a display module in which an impact-resistant layer is provided between a back film and a support component according to an implementation of the present disclosure.

FIG. 9 is a schematic structural diagram showing that an impact-resistant layer of a display module does not completely cover the rigid region according to an implementation of the present disclosure.

FIG. 10 is a schematic structural diagram of a display module in which an impact-resistant layer is provided between a flexible cover and a reflection reduction layer according to an implementation of the present disclosure, where the impact-resistant layer does not completely cover the rigid region.

FIG. 11 is a schematic structural diagram of a display module in which an impact-resistant layer is provided between a flexible cover and a reflection reduction layer according to an implementation of the present disclosure, where the impact-resistant layer is reused as an adhesive layer.

FIG. 12 is a schematic structural diagram of a display module in which an impact-resistant layer is provided between a display panel and a reflection reduction layer according to an implementation of the present disclosure, where the impact-resistant layer is reused as an adhesive layer.

FIG. 13 is a schematic structural diagram of a display module in which an impact-resistant layer is provided between a support component and a back film according to an implementation of the present disclosure, where the impact-resistant layer is reused as an adhesive layer.

FIG. 14 is a schematic structural diagram of a display module in which an impact-resistant layer is provided between a flexible cover and a reflection reduction layer and an impact-resistant layer is provided between a support component and a back film according to an implementation of the present disclosure; wherein the impact-resistant layers are reused as adhesive layers.

FIG. 15 is a schematic structural diagram of a display module in which an impact-resistant layer is provided between a flexible cover and a reflection reduction layer and an impact-resistant layer is provided between a display panel and a back film according to an implementation of the present disclosure, where the impact-resistant layers are reused as adhesive layers.

FIG. 16 is a schematic structural diagram of a display module in which an impact-resistant layer is provided between a flexible cover and a reflection reduction layer and an impact-resistant layer is provided between a display panel and the reflection reduction layer according to an implementation of the present disclosure, where the impact-resistant layers are reused as adhesive layers.

FIG. 17 is a schematic structural diagram showing an impact-resistant layer connected to an adjacent functional stacking layer through an adhesive layer according to an implementation of the present disclosure.

### DETAILED DESCRIPTION

Example implementations will now be described more fully with reference to the accompanying drawings. Example implementations may, however, be embodied in various forms and should not be construed as limited to the implementations set forth herein; rather, these implementations are provided so that the present disclosure will be thorough and complete and will fully convey the concepts of the example implementations to those skilled in the art. The same reference numerals in the drawings indicate the same or similar structures, and thus their detailed descriptions will be omitted. Furthermore, the drawings are merely schematic illustrations of the present disclosure and are not necessarily drawn to scale.

Although relative terms such as “upper” and “lower” are used in this specification to describe a relative relationship between one component in a figure and another component, these terms are used only for convenience, for example, these terms are based on the directions shown in the drawings. It can be understood that if a device shown in a figure is turned upside down, a component described as “upper” will become a “lower” component. When a structure is “on” another structure, it may mean that the structure is integrally formed on another structure, or that the structure is “directly” arranged on another structure, or that the structure is “indirectly” arranged on another structure through a further structure.

The terms “a”, “an”, “the”, “said” and “at least one” are used to indicate the presence of one or more elements/components/etc.; the terms “include” and “have” are open terms and means inclusive, and refers to that in addition to the listed elements/components and so on, there may be other elements/components and so on. The terms “first”, “second” and “third” etc. are used only as markers and are not intended to limit the number of associated objects.

An implementation of the present disclosure provides a display module and a display device in which the display module is applied. In some implementations of the present disclosure, the display device is a display device capable of realizing flexible display, such as a smartphone with a foldable screen, a smartphone with a sliding rollable screen, a smart watch with a wristband screen, etc.

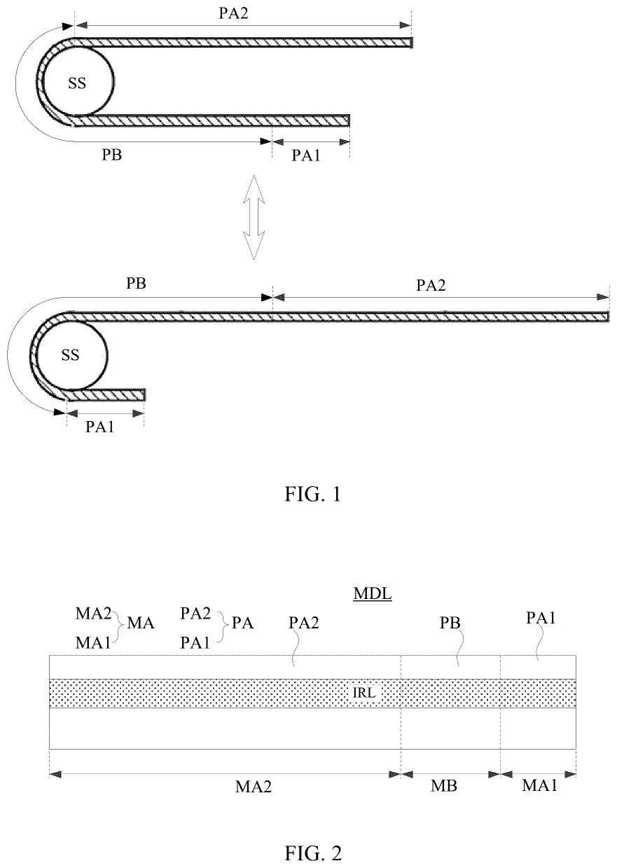

FIG. 1 provides an example introduction about an action procedure of a display module in a display device. In this example, the display device is a display device using a sliding and rolling technology. The display device may include a roller SS and a display module that cooperates with the roller SS.

The display module has a flexible portion PB and a first rigid sub-portion PA1 and a second rigid sub-portion PA2 located on both sides of the flexible portion PB. The flexible portion PB of the display module is arranged to cooperate with the roller SS, and the flexible portion of the display module can slide along with the rotation of the reel SS.

The second rigid sub-portion PA2 is provided at a light-exit side of the display device, and the first rigid sub-portion PA1 is received inside the display device. In a first display state, the second rigid sub-portion PA2 is used for display, and a part of the flexible portion PB immediately adjacent to the second rigid sub-portion PA2 is attached to the roller (depending on the configuration, this part may be used for display or may not be used for display), the other part of the flexible portion PB and the first rigid sub-portion PA1 are received inside the display device without performing display. The display device can be made to transition to a second display state by pulling the second rigid sub-portion PA2 outward. In the second display state, the first rigid sub-portion PA1 is received in the display device, and a part of the flexible portion PB immediately adjacent to the first rigid sub-portion PA1 is attached to the roller (depending on the configuration, this part may be used for display or may not be used for display), the other part of the flexible portion PB and the second rigid sub-portion PA2 are located at the light-exit side of the display device for performing display. In this way, compared with the first display state, the second display state has a larger display area. Specifically, if the width of the flexible portion PB (the dimension along the sliding roll direction) is πR+L, the width of the displayable region (the dimension along the sliding roll direction) in the second display state is larger than the width of the displayable region in the first display state by L, where R is the radius of the roller, and L is the sliding distance. Optionally, the sliding distance may be between 30 mm and 50 mm.

In an implementation, the display device can be in a form of a mobile phone under the first display state; the display device can transition to the second display state by sliding, thereby widening the display screen of the display device and thus allowing the display device to function as a tablet computer.

It can be understood that the display device illustrated in FIG. 1 is only an example of the display device of the present disclosure, and the display device of the present disclosure may also be other flexible display devices or rigid display device.

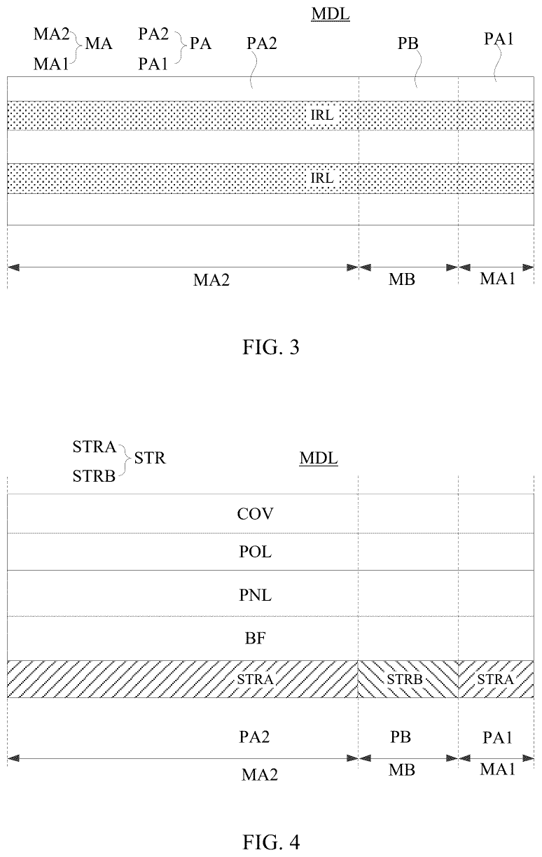

Referring to FIG. 2 and FIG. 3, the display module MDL provided by an implementation of the present disclosure may have a flexible region MB. The display module MDL includes at least one layer of flexible impact-resistant layer IRL. The impact-resistant layer at least covers the flexible region MB. When a local region of the impact-resistant layer IRL is subjected to an impact load, the elastic modulus of the local region is positively related to the impact load which the local region is subjected to.

According to the display module MDL provided by the implementation of the present disclosure, when the display module MDL is not subjected to an impact load or is basically not subjected to an impact load, for example, when the display module MDL remains static or when the display module MDL undergoes normal bending deformation in the flexible region MB, the elastic modulus of the impact-resistant layer IRL is very low, which makes the display module MDL have good flexibility under normal use. When the display module MDL is subjected to a normal impact, such as a pencil impact, the elastic modulus of the impact-resistant layer IRL in the local region (in the implementation, the location region may also be referred to as an impact region) for withstanding the impact load can quickly increases to withstand the impact load. At this time, in the impact region, especially the impact region located in the flexible region MB, the elastic modulus of the impact-resistant layer IRL increases rapidly, thereby reducing the deformation of the display module MDL, and thus improving the impact-resistant performance of the display module MDL, especially improving the impact-resistant performance of the display module MDL in the flexible region MB. Thus, the defect of insufficient impact-resistant performance of the display module MDL in the flexible region MB is overcome. When the impact load disappears, the elastic modulus of the impact area decreases, causing the impact region to regain flexibility.

In the implementation illustrated in FIG. 2, the display module MDL has an impact-resistant layer IRL. In the implementation illustrated in FIG. 3, the display module MDL has two impact-resistant layers IRL. It can be understood that in other implementations of the present disclosure, the display module MDL may also have three or more impact-resistant layers IRL.

The structure, principle and effect of the display module MDL according to implementations of the present disclosure will be further explained and described below with reference to the accompanying drawings.

Referring to FIG. 2, the display module MDL of this example includes a flexible portion PB and a rigid portion PA adjacent to the flexible portion PB. The region where the flexible portion PB is located is called a flexible region MB in the implementation of the present disclosure, and the region where the rigid portion PA is located is called a rigid region MA in the implementation of the present disclosure. The flexible portion PB has good deformation capability and can undergo at least one deformation of bending, winding, sliding and rolling, twisting, etc., or can undergo other feasible deformation(s). The rigid portion PA has strong rigidity and does not undergo obvious deformation under normal use. In the example of FIG. 2, the rigid portion PA includes a first rigid sub-portion PA1 and a second rigid sub-portion PA2 on both sides of the flexible portion PB. In other words, the rigid region MA includes a first rigid sub-region MA1 and a second rigid sub-region MA2 located on both sides of the flexible region MB.

In an example, the rigid portion may be a combination of a flexible film layer and a rigid support structure (such as the rigid support component STRA in FIG. 4). The flexible portion may be a combination of a flexible film layer and a deformable support structure (such as the flexible support component STRB in FIG. 4).

It can be understood that the display module MDL according to the implementation of the present disclosure is not limited to the structure illustrated in FIG. 2. For example, in some other implementations of the present disclosure, the flexible portion PB of the display module MDL may include a first flexible sub-portion and a second flexible sub-portion, and the rigid portion is sandwiched between the first flexible sub-portion and the second flexible sub-portion. As such, the flexible region MB may include a first flexible sub-region and a second flexible sub-region located on both sides of the rigid region MA. As another example, in some other implementations of the present disclosure, the rigid portion of the display module MDL may include a plurality of rigid sub-portions, the flexible portion PB of the display module MDL may include a plurality of flexible sub-portions, and the rigid sub-portions and the flexible sub-sections are sequentially spaced apart. In this way, the rigid region MA may include a plurality of rigid sub-regions, the flexible region MB may include a plurality of flexible sub-regions, and the rigid sub-regions and the flexible sub-regions are sequentially spaced apart. For another example, in some other implementations of the present disclosure, the display module MDL may be all flexible portion PB without being provided with a rigid portion. In this way, the entire region of the display module MDL is a flexible region MB.

FIG. 4 is a schematic cross-sectional structural diagram of a display module MDL (an impact-resistant layer is not shown) according to an implementation of the present disclosure. Referring to FIG. 4, in this example implementation, the display module MDL may include a plurality of functional stacking layers which are stacked in sequence. These functional stacking layers at least include a display panel PNL to implement display, and include an impact-resistant layer IRL stacked with the display panel PNL to improve the impact-resistant performance of the flexible region MB. As needed, these functional stacking layers may also include one or more of: a support component STR, a back film BF, a reflection reduction layer POL, a flexible cover COV, etc. The support component STR and the back film BF are located on the backlight side of the display panel PNL, the reflection reduction layer POL and the flexible cover COV are located on the light-exit side of the display panel PNL.

Optionally, the display panel PNL is a display panel using a flexible technology, such as a flexible organic electroluminescent diode (OLED) display panel, a flexible polymer electroluminescent diode (PLED) display panel, a flexible quantum dot organic electroluminescent diode (QD-OLED) display panel, a flexible quantum dot light-emitting diode (QLED) display panel, a mini light-emitting diode (Mini LED) display panel, or other flexible display panels.

The structure of the display panel is introduced and explained by taking the display panel being a flexible OLED display panel as an example. In this example, the flexible OLED display panel may include a flexible base substrate, a driving layer, a pixel layer and an encapsulation layer that are stacked in sequence. Of course, if necessary, a touch layer can also be provided on a side of the encapsulation layer away from the pixel layer. The driving layer may be provided with pixel driving circuit(s), and the pixel layer may be provided with OLED(s) as sub-pixel(s), and an OLED emits light under the driving of a corresponding pixel driving circuit. A side of the encapsulation layer is a light-exit side of the display panel, and a side of the flexible base substrate is the backlight side of the display panel.

Optionally, the support component STR may include a flexible support component STRB and a rigid support component STRA. The flexible support component STRB is used to support the flexible region of the MDL, and the rigid support component STRA is used to support the rigid region of the MDL.

Optionally, the reflection reduction layer POL may be a polarizer layer. Of course, if necessary, a color filter layer may also be used as the reflection reducing layer.

In the example of FIG. 4, the display module MDL includes a support component STR, a back film BF, a display panel PNL, a reflection reduction layer POL and a flexible cover COV that are stacked in sequence, and includes an impact-resistant layer provided between any two of the above functional stacking layers (not shown in FIG. 4). It can be understood that, as needed, the display module MDL can add additional new functional stacking layer(s) or omit one or more of the support component STR, the back film BF, the reduction reflection layer POL, and the flexible cover COV. In the implementation of the present disclosure, the display module MDL may include one impact-resistant layer or multiple impact-resistant layers.

In an implementation of the present disclosure, the display module MDL further includes a display panel PNL and a flexible cover COV which are stacked in sequence, and an impact-resistant layer IRL is provided between the display panel PNL and the flexible cover COV. In this implementation, the impact-resistant layer IRL is provided at a side of the display panel PNL close to the flexible cover COV, and thus the impact-resistant layer IRL is closer to the source of the impact load. In this way, when the display module MDL is subjected to impact, the strain rate which the impact region of the impact-resistant layer IRL is subjected to is higher, resulting in higher elastic modulus of the impact-resistant layer IRL in the impact region. This can better protect the display panel PNL and reduce the deformation of the display panel PNL. In addition, the impact-resistant layer is also closer to the encapsulation layer of the display panel, which can provide better protection for the encapsulation layer of the display panel and reduce the risk of damage or failure under an impact load due to high inorganic material content (the encapsulation layer is relatively brittle).

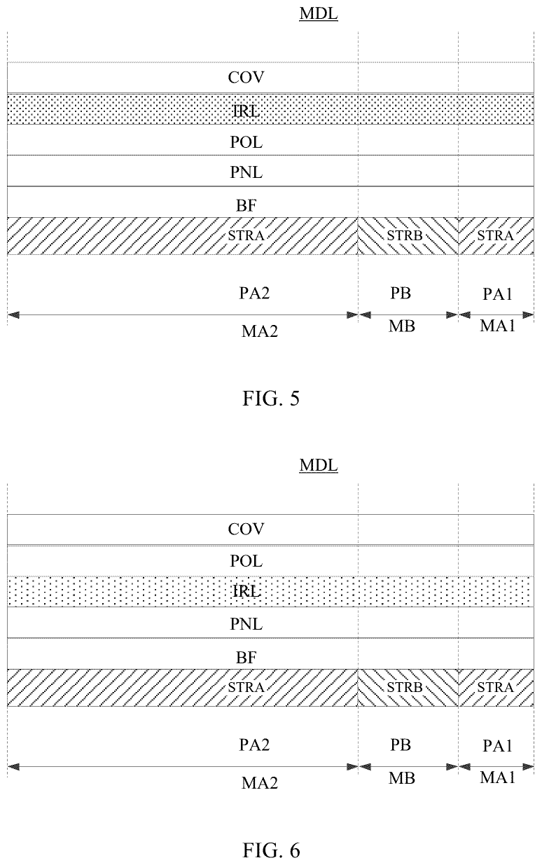

In an example of the implementation, referring to FIG. 5, the display module MDL further includes a reflection reduction layer POL located between the display panel PNL and the flexible cover COV. An impact-resistant layer IRL is provided between the reflection reduction layer POL and the flexible cover COV. In this example, the impact-resistant layer IRL is closer to the source of impact, and thus withstands a greater impact load and generates a greater strain rate, which allows the impact-resistant layer IRL to respond more fully to the impact load and increase its elastic modulus, thus providing better protection for the underneath display panel PNL (in a direction close to the support component).

For example, there is one impact-resistant layer IRL and the impact-resistant layer IRL is provided between the reflection reduction layer POL and the flexible cover COV. In this example, providing the impact-resistant layer IRL between the reflection reduction layer POL and the flexible cover COV can achieve optimal impact-resistant effect, and can maximize improvement of the impact-resistant performance of the display module MDL with only arranging one impact-resistant layer IRL. Also, according to relevant technologies, during the assembly process of the display module MDL, the materials of the reflection reduction layer POL and the flexible cover COV are generally supplied separately instead of being supplied in an integrated manner, which is conducive to improving the assembly flexibility of the display module MDL, especially improving supply chain flexibility. Of course, in other examples of the present disclosure, the impact-resistant layer IRL may be integrally made with one of the reflection reduction layer POL or the flexible cover COV.

In another example of the implementation, referring to FIG. 6, the display module MDL further includes a reflection reduction layer POL located between the display panel PNL and the flexible cover COV. An impact-resistant layer IRL is provided between the reflection reduction layer POL and the display panel PNL. In this situation, the impact-resistant layer IRL is also located at a side of the light-exit surface of the display panel PNL, and can withstand an impact load before the display panel PNL. The strain rate of the impact region when it is subjected to the impact load is also very high. Thus, the elastic modulus of the impact region is also very high, providing good protection for the display panel PNL. Also, the impact-resistant layer is placed immediately close to the encapsulation layer of the display panel, and thus it can greatly reduce the strain of the encapsulation layer, thereby improving the protection effect for the encapsulation layer. Since the encapsulation layer is most susceptible to damage under an impact load in the display panel, this arrangement can significantly improve the impact-resistant performance of the display module.

In other examples of implementations of the present disclosure, the display module MDL may be provided with an impact-resistant layer IRL between the display panel PNL and the reflection reduction layer POL, and may be provided with an impact-resistant layer IRL between the reflection reduction layer POL and the flexible cover COV at the same time. In this way, by providing two impact-resistant layers IRL at the side of the light-exit surface of the display panel PNL, a better protection effect can be achieved. Of course, it is understandable that the display module MDL can also be provided with three or more impact-resistant layers IRL between the display panel PNL and the flexible cover COV.

In an implementation of the present disclosure, the display module MDL further includes a display panel PNL and a support component STR which are stacked, and an impact-resistant layer IRL is provided between the display panel PNL and the support component STR. Although the impact-resistant layer IRL is arranged at a side of the backlight surface of the display panel PNL and is away from an impact, the impact-resistant layer IRL will still withstand the impact load when the display module MDL is impacted, and the impact region of the impact-resistant layer IRL still responds to the impact load and rapidly increases the elastic modulus, providing support with a high elastic modulus for the impact position of the display panel PNL. This can reduce the deformation of the display panel PNL due to impact, thereby reducing the risk of damage to the display panel PNL under the impact.

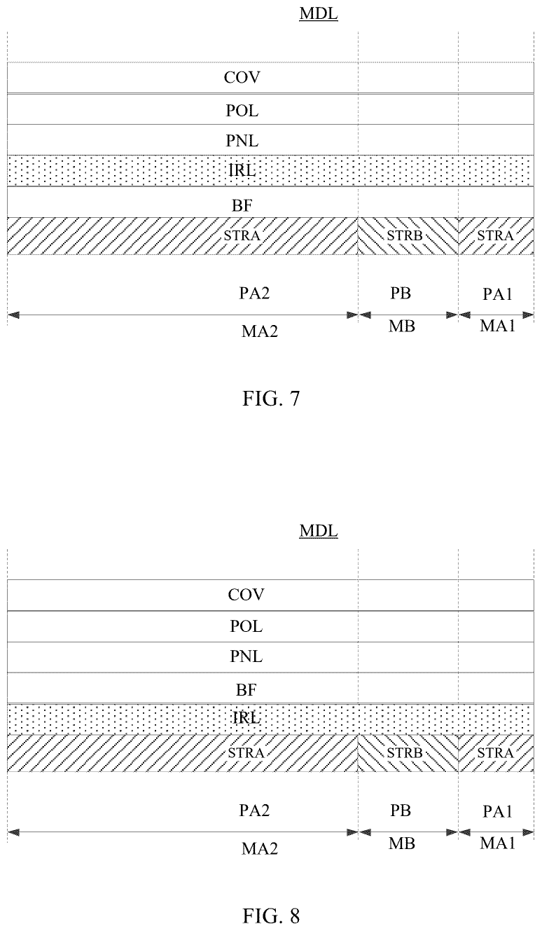

In an example of the implementation, referring to FIG. 7, the display module MDL further includes a back film BF located between the display panel PNL and the support component STR, and an impact-resistant layer IRL is provided between the display panel PNL and the back film BF. In this example, the impact-resistant layer IRL is provided close to the back of the display panel PNL; when the elastic modulus of the impact region of the impact-resistant layer IRL increases in response to the impact load, it is equivalent to providing support with a relatively high strength for the display panel PNL in the impact region. This can reduce the deformation of the display panel PNL and thereby improve the impact-resistant performance of the display module MDL.

In another example of the implementation, referring to FIG. 8, the display module MDL further includes a back film BF located between the display panel PNL and the support component STR, and an impact-resistant layer IRL is provided between the support component STR and the back film BF.

In other examples of implementations of the present disclosure, the display module MDL may be provided with an impact-resistant layer IRL between the display panel PNL and the back film BF, and may be provided with an impact-resistant layer IRL between the back film BF and the support component STR at the same time. In this way, by providing two impact-resistant layers IRL at a side of the backlight surface of the display panel PNL, a better protection effect can be achieved. Of course, it is understandable that the display module MDL may be provided with three or more impact-resistant layers IRL between the display panel PNL and the support component STR.

In other implementations of the present disclosure, the support component STR may include a multi-layer structure, and an impact-resistant layer IRL may be provided between different structural layers of the support component STR to improve the impact-resistant performance of the display module MDL.

In some implementations of the present disclosure, referring to FIG. 2, the display module MDL has a rigid region MA adjacent to the flexible region MB, and the impact-resistant layer IRL covers the rigid region MA and the flexible region MB. In other words, the impact-resistant layer IRL can cover the region where the display module MDL is located, especially the display region of the display module MDL. On the one hand, this can improve the impact-resistant performance of both the rigid region MA and the flexible region MB. On the other hand, this facilitates the attachment or assembly of the impact-resistant layer IRL, thereby improving the manufacture efficiency of the display module MDL and reducing the cost of the display module MDL.

In some other implementations of the present disclosure, referring to FIG. 9, the display module MDL has a rigid region MA adjacent to the flexible region MB. The display module MDL also includes a filling layer DUML. The thickness of the filling layer DUML is the same as the thickness of the impact-resistant layer IRL and the filling layer DUML is arranged in the same layer as the impact-resistant layer IRL. The filling layer DUML is provided in the rigid region MA. Furthermore, the filling layer DUML and the impact-resistant layer IRL are complementary, that is, the patterns of the filling layer DUML and the impact-resistant layer IRL are spliced with each other to form a whole. In this implementation, the impact-resistant layer IRL can specifically improve the impact-resistant performance of the flexible region MB. At the same time, the setting of the filling layer DUML can ensure the smoothness of other functional stacking layers, thereby ensuring the performance of the display module MDL.

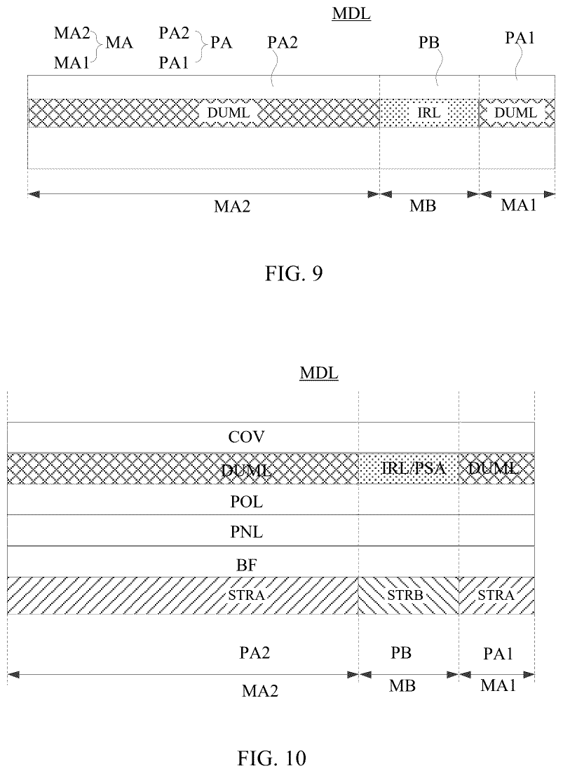

For example, referring to FIG. 10, the display module MDL includes a display panel PNL, a reflection reduction layer POL and a flexible cover COV which are stacked in sequence. An impact-resistant layer IRL and a filling layer DUML are provided between the reflection reduction layer POL and the flexible cover COV. The impact-resistant layer IRL covers the flexible region MB, and the filling layer DUML covers the rigid region MA. The filling layer DUML is arranged in the same layer as the impact-resistant layer IRL with equal thickness as the impact-resistant layer IRL, and patterns of the filling layer DUML and the impact-resistant layer IRL are complementary.

In an example, the material of the filling layer DUML may be polyimide. Of course, the filling layer DUML can also use other organic materials.

It can be understood that in other examples of the present disclosure, the impact-resistant layer IRL and the filling layer DUML which are in the same layer may also be provided between other functional stacking layers. It can also be understood that in other examples of the present disclosure, the display module MDL can also be provided with two or more layers of complementary structure. The complementary structure of each layer includes an impact-resistant layer IRL covering the flexible region MB and a filling layer DUML covering the rigid region MA.

It can be understood that in other implementations of the present disclosure, the display module MDL may include at least one impact-resistant layer IRL covering the rigid region MA and the flexible region MB, and at least one layer of complementary structure. The complementary structure includes an impact-resistant layer IRL and a filling layer DUML arranged in the same layer. In this way, the display module MDL may include at least two impact-resistant layers IRL, where at least one impact-resistant layer IRL may cover the flexible region MB and the rigid region MA. At least one impact-resistant layer IRL may mainly cover the flexible region MB, and may not cover the rigid region MA or may cover only a part of the rigid region MA adjacent to the flexible region MB.

In an implementation of the present disclosure, the strain rate of the local region of the impact-resistant layer IRL when subjected to the impact load is not greater than 100000 s⁻¹. In other words, when the impact-resistant layer IRL withstands a strain rate of no more than 100000 s⁻¹, its function does not fail and it still has a high elastic modulus. It can be understood that when an impact object such as a pen/pencil is dropped and impacts the display module MDL, the higher the height of the impact object, the greater the impact load when the impact object impacts the display module MDL, and the greater the generated strain rate when the impact region of the impact-resistant layer IRL responds to the impact load.

In an implementation of the present disclosure, the strain rate can be calculated according to the following simple formula: V/D, where V is the instantaneous speed when the impact object hits the display module MDL, and D is the thickness of the impact-resistant layer IRL.

Optionally, if the strain rate of the local region (impact region) of the impact-resistant layer IRL when subjected to the impact load is not less than 100 s⁻¹, the elastic modulus of the local region is not less than 0.01 MPa, especially it can be not less than 0.1 MPa. When the display module MDL is subjected to a significant impact, the strain rate of the impact-resistant layer IRL can reach 100 s⁻¹ or more. At this time, the elastic modulus of the impact region increases to 0.01 MPa or more, especially to 0.1 MPa or more, which is beneficial to reducing the influence of the impact on display panel PNL.

In an example, the strain rate of the local region of the impact-resistant layer IRL when subjected to the impact load is 100 s⁻¹˜10000 s⁻¹, and the elastic modulus of the local region is 0.01 MPa˜3 GPa. For example, if the strain rate of the local region of the impact-resistant layer IRL when subjected to the impact load is 100 s⁻¹˜10000 s⁻¹, the elastic modulus of the local region is 0.1 MPa˜3 GPa, especially the elastic modulus may be 0.5 GPa˜1.5 GPa. Generally, the strain rate of the impact-resistant layer IRL caused by a regular pencil-impacted test is 100 s⁻¹˜10000 s⁻¹. During the pencil-impacted test, the elastic modulus of the impact region of the impact-resistant layer IRL increases rapidly to resist the impact load and reduce damage to the display panel PNL caused by pencil. It can be understood that the greater the height of the pencil, the greater the strain rate of the impact region of the impact-resistant layer IRL.

In an example, when the local region of the impact-resistant layer IRL does not withstand an impact load, the elastic modulus of the local region is between 1 KPa˜50 KPa. For example, when the flexible region MB of the display module MDL is in the sliding and rolling deformation process, the display module MDL basically does not withstand an impact. At this time, the elastic modulus of the impact-resistant layer IRL is 1 KPa˜300 KPa, especially the elastic modulus may be 1 KPa˜50 KPa and the impact-resistant layer IRL is very soft. This can ensure the flexibility of the flexible region MB of the display module MDL.

In an example, when the local region of the impact-resistant layer IRL is not subjected to an impact load, the elastic modulus of the local region is 20 KPa˜40 KPa; the strain rate of the local region of the impact-resistant layer IRL when subjected to the impact load is 100 s⁻¹˜10000 s⁻¹, and the elastic modulus of the impact region of the impact-resistant layer IRL is 0.5 GPa˜1.5 GPa. In an implementation of the present disclosure, the thickness of the impact-resistant layer IRL is 10 microns˜150 microns. It can be understood that the greater the thickness of the impact-resistant layer IRL, the better the impact-resistant performance.

In an example, the thickness of the impact-resistant layer IRL may be 15 microns˜75 microns to realize a balance between improving the impact-resistant performance of the display module MDL and reducing the thickness of the display module MDL. For example, the thickness of the impact-resistant layer IRL may be one of 15 microns, 25 microns, 35 microns, 50 microns, and 75 microns.

In an implementation of the present disclosure, the impact-resistant layer IRL includes a dispersion matrix and an impact-resistant polymer dispersed in the dispersion matrix. Of course, it can be understood that, if necessary, the above-mentioned impact-resistant layer IRL may also include required additives, such as a stabilizer, a leveling agent, etc. In this implementation, the impact-resistant polymer is dispersed in a dispersion matrix, and the dispersion matrix can be used to adjust one or more of parameters and performance such as the film-forming property, light transmittance, the elastic modulus without impact load, the thickness of the impact-resistant layer IRL, and so on. In particular, with the help of the dispersion effect of the dispersion matrix, some impact-resistant polymers with poor film-forming property or too strong fluidity can be used in the impact-resistant layer IRL, expanding the range of selection of impact-resistant polymers and enabling the optimization of the impact-resistant layer IRL.

In an example of the implementation, the dispersion matrix is an adhesive. In this way, the impact-resistant layer IRL has adhesion and can be bonded to other functional stacking layer(s). For example, the impact-resistant layer IRL can be directly connected to an adjacent functional stacking layer.

Optionally, the adhesive is a pressure-sensitive adhesive, a heat-sensitive adhesive or a photo-sensitive adhesive. In this way, the impact-resistant layer IRL can replace an adhesive layer in the display module MDL to achieve bonding between two adjacent functional stacking layers. In other words, in the display module MDL of the example, at least one adhesive layer PSA in the display module MDL may have an impact-resistant capability as the impact-resistant layer IRL. This can improve the impact-resistant performance of the display module MDL while avoiding increasing the thickness of the display module MDL.

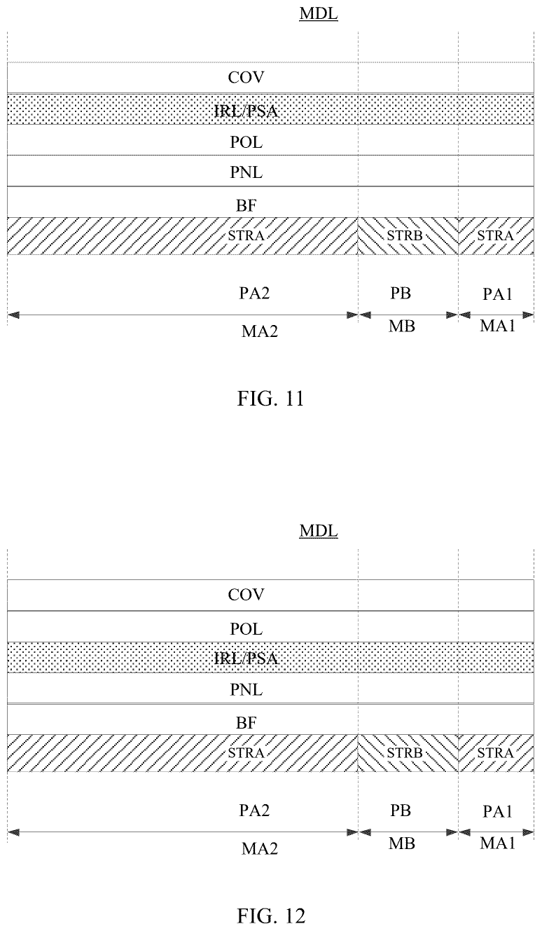

For example, in the example of FIG. 11, a flexible cover COV and a reflection reduction layer POL are bonded through an adhesive layer PSA. In this example, the adhesive layer PSA is mixed with an impact-resistant polymer and may also serve as the impact-resistant layer IRL. In this way, it is possible to provide the impact-resistant layer IRL between the flexible cover COV and the reflection reduction layer POL without additionally introducing any new film layer(s).

For another example, in the example of FIG. 12, a display panel PNL and a reflection reduction layer POL are bonded through an adhesive layer PSA. In this example, the adhesive layer PSA is mixed with an impact-resistant polymer and may also serve as the impact-resistant layer IRL. In this way, it is possible to provide the impact-resistant layer IRL between the display panel PNL and the reflection reduction layer POL without additionally introducing any new film layer(s).

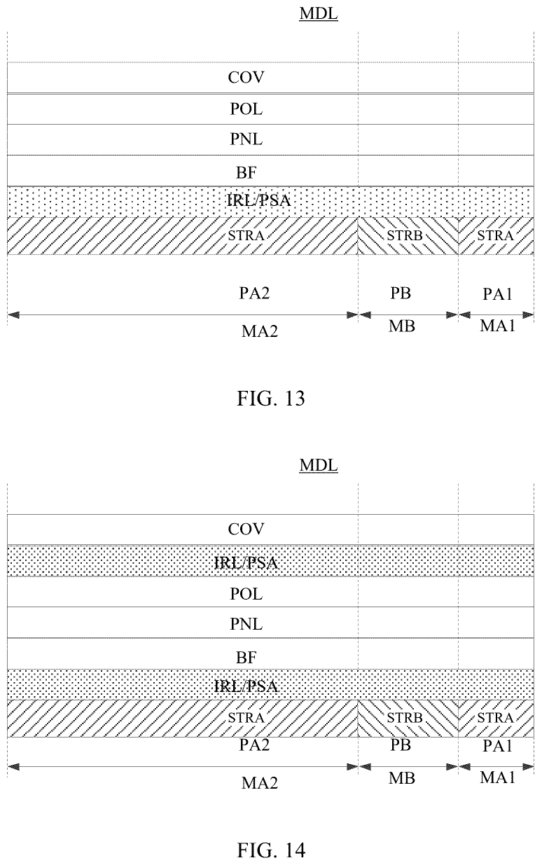

For another example, in the example of FIG. 13, a back film BF and a support component STR are bonded through an adhesive layer PSA. In this example, the adhesive layer PSA is mixed with an impact-resistant polymer and may also serve as the impact-resistant layer IRL. In this way, it is possible to provide the impact-resistant layer IRL between the support component STR and the back film BF without additionally introducing any new film layer(s).

In some other examples of implementations of the present disclosure, the display module MDL may be provided with multiple impact-resistant layers IRL, and each impact-resistant layer IRL may simultaneously serve as an adhesive layer PSA. In this way, multiple impact-resistant layers IRL can be added to the display module MDL without additionally increasing the thickness of the display module MDL, thereby obtaining better impact-resistant performance.

For example, in the example of FIG. 14, an impact-resistant layer IRL is provided between a flexible cover COV and a reflection reduction layer POL, and an impact-resistant layer IRL is provided between a support component STR and a back film BF. Both of the two impact-resistant layers IRL can simultaneously serve as adhesive layers PSA and play a bonding role.

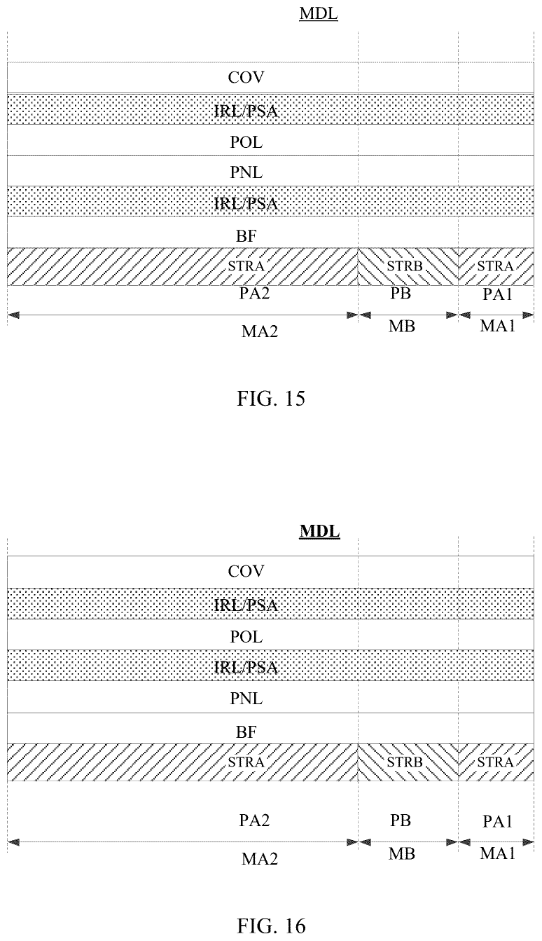

For another example, in the example of FIG. 15, an anti-impact layer IRL is provided between a flexible cover COV and a reflection reduction layer POL, and an anti-impact layer IRL is provided between a display panel PNL and a back film BF. Both of the two impact-resistant layers IRL can simultaneously serve as adhesive layers PSA and play a bonding role.

For another example, in the example of FIG. 16, an impact-resistant layer IRL is provided between a flexible cover COV and a reflection reduction layer POL, and an impact-resistant layer IRL is provided between a display panel PNL and a reflection reduction layer POL. Both of the two impact-resistant layers IRL can simultaneously serve as adhesive layers PSA and play a bonding role. Since the two impact-resistant layers IRL have a significant effect in improving the impact-resistant performance of the display module MDL, they can better improve the impact-resistant performance without causing increase of the thickness of the display module MDL due to setting of additional film layer(s), while light attenuation caused by additional film layer(s) can also be avoided.

Of course, it can be understood that an adhesive layer at other positions of the present disclosure can also be set as an impact-resistant layer IRL to improve the impact-resistant performance of the display module MDL.

In an example of the implementation, the mass content of the impact-resistant polymer in the impact-resistant layer IRL is between 10% and 90%. Further, the mass content of the impact-resistant polymer in the impact-resistant layer IRL is between 10% and 50%. For example, the mass content of the impact-resistant polymer in the impact-resistant layer IRL is between 20% and 40%. As an example, the mass content of the impact-resistant polymer in the impact-resistant layer IRL is 20%, 25%, 30%, 35% or 40%.

In another implementation of the present disclosure, the impact-resistant layer IRL is mainly formed by the impact-resistant polymer. In other words, the impact-resistant polymer in the impact-resistant layer IRL may not be dispersed in a dispersion medium but forms a film directly. Of course, if necessary, the impact-resistant layer IRL may also include other additives, such as a leveling agent, a stabilizer, etc. In the implementation of the present disclosure, the impact-resistant layer IRL is mainly formed by the impact-resistant polymer. This does not strictly limit the impact-resistant layer IRL to only contain the impact-resistant polymer, but means that the main component in the impact-resistant layer IRL is the impact-resistant polymer, and other components are additives. In an implementation of the present disclosure, the main component refers to a component with a mass content of not less than 10% in the impact-resistant layer IRL, especially a component with a mass content of not less than 5%. For example, in an example, the impact-resistant layer IRL being mainly formed by the impact-resistant polymer means that: in addition to the impact-resistant polymer, the impact-resistant layer IRL also includes at least one additive; wherein the mass content of any one of the additives is less than 5%.

In an example of the implementation, a precursor mixture of the impact-resistant layer IRL may be directly applied as a film. In another example, the precursor mixture of the impact-resistant layer IRL also contains a solvent, and at least part of the solvent can be volatilized during coating to form a film.

In an example of the implementation, the impact-resistant layer IRL may not have adhesion, or may not have enough adhesion to function as an adhesive layer. In this case, both sides of the impact-resistant layer IRL can be connected to adjacent functional stacking layers through adhesive layers.

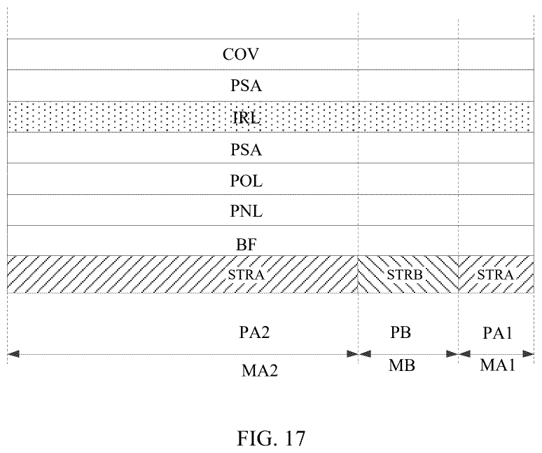

For example, in the example of FIG. 17, an impact-resistant layer IRL is provided between a flexible cover COV and a reflection reduction layer POL. An adhesive layer PSA is provided between the impact-resistant layer IRL and the flexible cover COV to realize the connection between the impact-resistant layer IRL and the flexible cover COV. An adhesive layer PSA is provided between the impact-resistant layer IRL and the reflection reduction layer POL to achieve the connection between the impact-resistant layer IRL and the reflection reduction layer POL.

In an implementation of the present disclosure, the impact-resistant polymer includes at least one of the following polymers or a modified polymer of at least one of the following polymers:
polypropylene foam, polystyrene foam, ethylene-vinyl acetate copolymer, borosilicate oligomer.

These polymers or their modified polymers are all transparent polymers, and their elastic modulus increases as the strain rate increases. When these impact-resistant polymers are applied to the impact-resistant layer IRL, they can increase the elastic modulus in response to an impact load, provide support and protection for the display panel PNL, and reduce the risk of failure or damage of the display panel PNL under the impact load.

In an example of the implementation, the borosilicate oligomer can be synthesized from boric acid and dimethylhydroxysilyl ether oligomer (or the borosilicate oligomer may be considered as being synthesized from boric acid and a product of polydimethylsiloxane oligomer), and the chemical formula may be as follows:

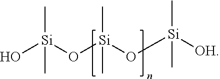

In an example of the implementation, the modified polymer refers to a modified polymer formed by polymerizing a precursor component of the polypropylene foam and/or a precursor component of the polystyrene foam and the polymer.

Of course, it can be understood that the above-mentioned impact-resistant polymers are only examples of impact-resistant polymers that can be selected in implementations of the present disclosure. In other implementations of the present disclosure, other impact-resistant polymers, that are capable of increasing elastic modulus in response to an increase in strain rate, may be selected. Furthermore, when the impact-resistant layer IRL is provided at a side of the backlight surface of the display panel PNL, the impact-resistant polymer in the impact-resistant layer IRL can also be an impact-resistant polymer that is opaque or has low light transmittance.

It can be understood that when the display module MDL has multiple impact-resistant layers IRL, the impact-resistant polymers of any two impact-resistant layers IRL may be the same or different.

Other implementations of the present disclosure will be readily apparent to those skilled in the art from consideration of the specification and practice of the present disclosure. The present disclosure is intended to cover any variations, uses, or adaptations of the present disclosure that follow the general principles of the present disclosure and include common knowledge or customary technical means in the technical field that are not disclosed herein. It is intended that the specification and examples be considered as illustrative only.

1. A display module having a flexible region and rigid regions located at both sides of the flexible region, wherein the display module comprises at least one flexible impact-resistant layer, and the impact-resistant layer at least covers the flexible region;
wherein when a local region of the impact-resistant layer is subjected to an impact load, an elastic modulus of the local region is positively related to the impact load which the local region is subjected to.

2. The display module according to claim 1, wherein a strain rate of the local region of the impact-resistant layer when subjected to the impact load is not greater than 100000 s⁻¹.

3. The display module according to claim 1, wherein when a strain rate of the local region of the impact-resistant layer when subjected to the impact load is not smaller than 100 s⁻¹, the elastic modulus of the local region is not lower than 0.1 MPa.

4. The display module according to claim 1, wherein response to a strain rate of the local region of the impact-resistant layer when subjected to the impact load is between 100 s⁻¹ and 10000 s⁻¹, the elastic modulus of the local region is between 0.01 MPa and 3 GPa.

5. The display module according to claim 1, wherein when the local region of the impact-resistant layer is not subjected to the impact load, the elastic modulus of the local region is between 1 KPa and 300 KPa; or
wherein a thickness of the impact-resistant layer is between 10 microns and 150 microns.

6. (canceled)

7. The display module according to claim 1, wherein the impact-resistant layer comprises a dispersion matrix and an impact-resistant polymer dispersed in the dispersion matrix.

8. The display module according to claim 7, wherein the dispersion matrix is an adhesive, and the impact-resistant layer is directly connected to an adjacent functional stacking layer.

9. The display module according to claim 8, wherein the adhesive is a pressure-sensitive adhesive, a heat-sensitive adhesive or a photo-sensitive adhesive.

10. The display module according to claim 7, wherein a mass content of the impact-resistant polymer in the impact-resistant layer is between 10% and 90%.

11. The display module according to claim 7, wherein a mass content of the impact-resistant polymer in the impact-resistant layer is between 10% and 50%.

12. The display module according to claim 1, wherein the impact-resistant layer is mainly formed by an impact-resistant polymer.

13. The display module according to claim 7, wherein the impact-resistant polymer comprises at least one of the following polymers or a modified polymer of at least one of the following polymers:
polypropylene foam, polystyrene foam, ethylene-vinyl acetate copolymer, or borosilicate oligomer.

14. The display module according to claim 13, wherein the modified polymer refers to a modified polymer formed by polymerizing at least one of a precursor component of the polypropylene foam or a precursor component of the polystyrene foam with the polymer.

15. The display module according to claim 1, wherein the display module further comprises a display panel and a flexible cover which are stacked, and the impact-resistant layer is provided between the display panel and the flexible cover.

16. The display module according to claim 15, wherein the display module further comprises a reflection reduction layer located between the display panel and the flexible cover;
wherein the impact-resistant layer is provided between the display panel and the reflection reduction layer, and/or the impact-resistant layer is provided between the reflection reduction layer and the flexible cover.

17. The display module according to claim 1, wherein the display module further comprises a display panel and a support component, and the impact-resistant layer is provided between the display panel and the support component.

18. The display module according to claim 17, wherein the display module further comprises a back film located between the display panel and the support component;
wherein the impact-resistant layer is provided between the display panel and the back film, and/or the impact-resistant layer is provided between the back film and the support component.

19. The display module according to claim 1, wherein the impact-resistant layer covers the rigid regions and the flexible region.

20. The display module according to claim 1, wherein the display module further comprises a filling layer, the filing layer has a thickness which is the same as a thickness of the impact-resistant layer and is arranged in a same layer as the impact-resistant layer, and the filling layer is provided in the rigid regions.

21. A display device, comprising a roller and a display module,
wherein display module has a flexible region and rigid resions located at both sides of the flexible region, wherein the display module comprises at least one flexible impact-resistant layer, and the impact-resistant layer at least covers the flexible region;
wherein when a local region of the impact-resistant layeris subjected to an impact load, an elastic modulus of the local region of positively related to the impact load which the local region is subjected to;
wherein the flexible region of the display module is slidable around the roller.
